(19) United States
(12) Patent Application Publication
(10) Pub. No.: US 2025/0226347 A1
(43) Pub. Date: Jul. 10, 2025

(54) ADHESIVE FILM FOR SEMICONDUCTORS, DICING DIE BONDING FILM, AND METHOD FOR PRODUCING SEMICONDUCTOR DEVICE

(71) Applicant: Resonac Corporation, Minato-ku, Tokyo (JP)

(72) Inventors: Takaaki NIWA, Minato-ku, Tokyo (JP); Kohei TANIGUCHI, Minato-ku, Tokyo (JP); Takahiro KURODA, Minato-ku, Tokyo (JP); Yoshinobu OZAKI, Minato-ku, Tokyo (JP); Keisuke OKAWARA, Minato-ku, Tokyo (JP)

(21) Appl. No.: 18/850,559

(22) PCT Filed: Mar. 24, 2023
(86) PCT No.: PCT/JP2023/011989

§ 371 Date: Sep. 25, 2024

(30) Foreign Application Priority Data
Mar. 30, 2022 (JP) 2022-056403

(51) Int. Cl. H01L 23/00; C09J 163/00; H01L 21/56; H01L 21/683

(52) U.S. Cl. CPC H01L 24/29; C09J 163/00; H01L 24/83; C09J 2203/326; H01L 21/56; H01L 21/6836; H01L 2224/2929; H01L 2224/29291; H01L 2224/29386; H01L 2224/83862

(57) ABSTRACT

A thermosetting adhesive film for semiconductors is provided, the adhesive film being used to bond a semiconductor chip to an adherend while embedding a wire connected to another semiconductor chip. The adhesive film has a minimum melt viscosity of 2500 Pa·s or more and 10000 Pa·s or less in a range of 90° C. to 180° C. The minimum melt viscosity is a value determined by measurement on a dynamic viscoelasticity of the adhesive film within a temperature range including a range of 90° C. to 180° C. under the conditions of a temperature increasing rate of 5° C./min and a frequency of 1 Hz.

### TECHNICAL FIELD

The present disclosure relates to an adhesive film for semiconductors, a dicing die-bonding film, and a method for manufacturing a semiconductor device.

### BACKGROUND ART

An adhesive film for semiconductors, which is used to bond a semiconductor chip to an adherend, may be necessary to embed a wire that is connected to another semiconductor chip (for example, Patent Literature 1). Such an adhesive film with the wire-embedding type is demanded to have a certain degree of fluidity in a thermal curing process in order to appropriately embed the wire.

### CITATION LIST

### Patent Literature

Patent Literature 1: Japanese Patent No. 6135202

### SUMMARY OF INVENTION

### Technical Problem

However, in the adhesive film in the related art, which has a certain degree of fluidity, deformation occurs in a thickness direction in the thermal curing process. As a result, a portion locally thinned may be produced in the adhesive film. The portion locally thinned in the adhesive film may cause, for example, a crack in the semiconductor chip.

An aspect of the present disclosure relates to a thermosetting adhesive film for semiconductors used to bond a semiconductor chip to an adherend while embedding a wire connected to another semiconductor chip, and relates to suppressing local deformation of the adhesive film in the thickness direction, which is associated with thermal curing.

### Solution to Problem

An aspect of the present disclosure relates to a thermosetting adhesive film for semiconductors used to bond a semiconductor chip to an adherend while embedding a wire connected to another semiconductor chip. The adhesive film has a minimum melt viscosity of 2500 Pa·s or more and 10000 Pa·s or less in a range of 90° C. to 180° C. The maximum value of tan δ and the minimum melt viscosity are values determined by measurement on a dynamic viscoelasticity of the adhesive film within a temperature range including a range of 90° C. to 180° C. under the conditions of a temperature increasing rate of 5° C./min and a frequency of 1 Hz under the conditions of a temperature increasing rate of 5° C./min and a frequency of 1 Hz.

Another aspect of the present disclosure relates to a dicing die-bonding film comprising a dicing film and the above-described adhesive film for semiconductors provided on the dicing film.

Still another aspect of the present disclosure relates to a method for manufacturing a semiconductor device, the method comprising: disposing a second semiconductor chip and an adhesive film over a structure comprising a substrate and a first semiconductor chip mounted on the substrate such that the adhesive film is sandwiched between the structure and the second semiconductor chip; and thermally curing the adhesive film to bond the second semiconductor chip to the structure. The adhesive film can be the above-described adhesive film for semiconductors. The first semiconductor chip is connected to a wire, and a part or the whole of the wire is embedded by the adhesive film.

### Advantageous Effects of Invention

For the thermosetting adhesive film for semiconductors used to bond a semiconductor chip to an adherend while embedding a wire connected to another semiconductor chip, it is possible to suppress local deformation of the adhesive film in the thickness direction, which is associated with thermal curing.

### BRIEF DESCRIPTION OF DRAWINGS

FIG. 1 is a cross-sectional view illustrating an example of a laminated film including an adhesive film.

FIG. 2 is a cross-sectional view illustrating an example of a method for manufacturing a semiconductor device.

FIG. 3 is a cross-sectional view illustrating the example of the method for manufacturing a semiconductor device.

FIG. 4 is a cross-sectional view illustrating the example of the method for manufacturing a semiconductor device.

FIG. 5 is a cross-sectional view illustrating the example of the method for manufacturing a semiconductor device.

FIG. 6 is a cross-sectional view illustrating the example of the method for manufacturing a semiconductor device.

FIG. 7 is a graph illustrating a relationship between a shear viscosity and a temperature of an adhesive film.

FIG. 8 is a graph illustrating a relationship between tan δ and a temperature of the adhesive film.

FIG. 9 is a schematic cross-sectional view illustrating an adherent for evaluation, which is used to evaluate deformation of the adhesive film associated with curing.

### DESCRIPTION OF EMBODIMENTS

The present invention is not limited to the following examples. In the following examples, the components (including steps and other features) are not mandatory unless otherwise specified. The sizes of the components in each drawing are conceptual, and the relative relationship between the sizes of the components is not limited to that illustrated in each drawing. Numerical values and ranges thereof exemplified below are not intended to limit the present disclosure.

In the present specification, a numerical range indicated using “to” indicates a range including numerical values described before and after “to” as a minimum value and a maximum value, respectively. In the numerical ranges gradually described in the present specification, the upper limit value or the lower limit value described in one numerical range may be replaced with the upper limit value or the lower limit value in another gradually described numerical range. In the numerical ranges described in the present specification, the upper limit value or the lower limit value of a numerical range may be replaced with values illustrated in Examples.

In the present specification, (meth)acrylate means acrylate or

methacrylate corresponding thereto. The same applies to other similar expressions such as a (meth)acryloyl group and a (meth)acrylic copolymer.

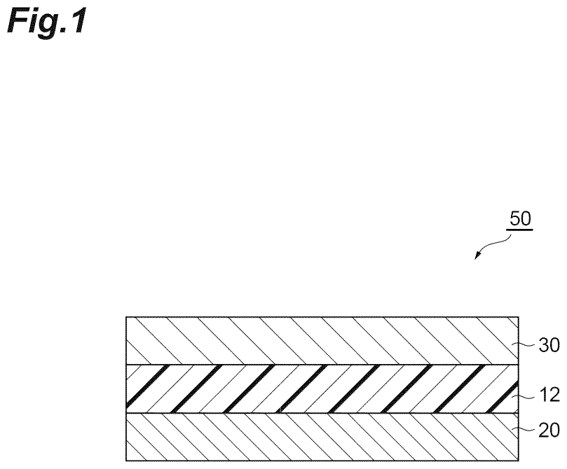

FIG. 1 is a cross-sectional view illustrating an example of a laminated film including an adhesive film. A laminated film 50 illustrated in FIG. 1 includes a base material 20, an adhesive film 12, and a protective film 30 in this order. For the adhesive film, the adhesive film 12 can be a thermosetting adhesive film for semiconductors configured to bond a semiconductor chip to an adherend while embedding a wire connected to another semiconductor chip. The base material 20 may be a dicing film, and in this case, the laminated film 50 can be used as a dicing die-bonding film.

The adhesive film 12 may have a minimum melt viscosity of 2500 Pa·s or more and 10000 Pa·s or less in a range of 90° C. to 180° C. The adhesive film 12 may have a maximum value of tan δ of 1.0 or less in a range of 90° C. to 180° C. The minimum melt viscosity and the maximum value of tan δ are values determined by measurement on a dynamic viscoelasticity of the adhesive film 12 within a temperature range including a range of 90° C. to 180° C. under the conditions of a temperature increasing rate of 5° C./min and a frequency of 1 Hz.

The minimum melt viscosity of the adhesive film means the minimum value of a shear viscosity (or complex viscosity η*) measured by dynamic viscoelasticity measurement on the adhesive film 12. The shear viscosity of the adhesive film 12 usually decreases as the temperature increases, followed by increasing as a curing reaction proceeds. Provided that the minimum melt viscosity of the adhesive film 12 is 10000 Pa·s or less, the adhesive film 12 can appropriately embed a wire or other components. From the same viewpoint, the minimum melt viscosity of the adhesive film 12 may be 9000 Pa·s or less, 8500 Pa·s or less, 8000 Pa·s or less, 7500 Pa·s or less, 7000 Pa·s or less, 6500 Pa·s or less, 6000 Pa·s or less, or 5500 Pa·s or less.

Maintaining the shear viscosity of the adhesive film 12 at a high level to a certain degree in a range of 90° C. to 180° C. can also contribute to suppressing deformation of the adhesive film 12 in the curing process. From this viewpoint, the minimum melt viscosity of the adhesive film 12 in a range of 90° C. to 180° C. may be 2500 Pa·s or more, 3000 Pa·s or more, or 3500 Pa·s or more.

In a case where the tan δ of the adhesive film 12 is 1.0 or less in a range of 90° C. to 180° C., deformation of the adhesive film 12 in a thermal curing process is further likely to be suppressed. From the same viewpoint, the maximum value of tan δ of the adhesive film 12 in a range of 90° C. to 180° C. may be 0.95 or less, 0.90 or less, 0.85 or less, 0.80 or less, 0.75 or less, or 0.70 or less, or may be 0.50 or more.

The thickness of the adhesive film 12 may be, for example, 1 μm or more, 3 μm or more, 20 μm or more, 25 μm or more, 30 μm or more, 35 μm or more, 40 μm or more, or 50 μm or more, and may be 200 μm or less, 150 μm or less, 120 μm or less, 80 μm or less, or 60 μm or less. From the viewpoint that the adhesive film 12 is used to bond a semiconductor chip to an adherend while embedding a wire connected to another semiconductor chip, the thickness of the adhesive film 12 may be 25 to 80 μm.

The adhesive film 12 contains, for example, a thermosetting resin and a curing agent that reacts with the thermosetting resin. The thermosetting resin is a compound to form a crosslinked structure by a curing reaction including a reaction with a curing agent and/or self-polymerization, and examples thereof include an epoxy resin that is a compound having an epoxy group. Examples of the epoxy resin include a bisphenol A epoxy resin, a bisphenol F epoxy resin, a bisphenol S epoxy resin, a phenol novolac epoxy resin, a cresol novolac epoxy resin, a bisphenol A novolac epoxy resin, a bisphenol F novolac epoxy resin, a stilbene epoxy resin, a triazine skeleton-containing epoxy resin, a fluorene skeleton-containing epoxy resin, a triphenol phenolmethane epoxy resin, a biphenyl epoxy resin, a xylylene epoxy resin, a biphenyl aralkyl epoxy resin, a naphthalene epoxy resin, and a diglycidyl ether compound derived from a polyfunctional phenol compound or a polycyclic aromatic compound (anthracene or other compounds). These may be used singly or in combination of two or more kinds thereof. The epoxy resin may be in combination of an o-cresol novolac epoxy resin and a bisphenol F epoxy resin and/or a bisphenol A epoxy resin.

The curing agent combined with the epoxy resin as the thermosetting resin can include, for example, a phenol resin. Examples of the phenol resin used as the curing agent include a novolac phenol resin, an allylated bisphenol A, an allylated bisphenol F, an allylated naphthalenediol, a phenol aralkyl resin, and a naphthol aralkyl resin. These may be used singly or in combination of two or more kinds thereof. The novolac phenol resin is obtained by condensation or co-condensation of phenols (for example, phenol, cresol, resorcin, catechol, bisphenol A, bisphenol F, phenylphenol, aminophenol) and/or naphthols (for example, α-naphthol, β-naphthol, dihydroxynaphthalene) with a compound having an aldehyde group such as formaldehyde under an acidic catalyst. The phenol aralkyl resin and the naphthol aralkyl resin are synthesized from phenols such as phenol novolac and phenol and/or naphthols, and dimethoxy paraxylene or bis(methoxymethyl) biphenyl.

The total content of the thermosetting resin and the curing agent may be, for example, 10% by mass or more or 15% by mass or more, and may be 80% by mass or less, 75% by mass or less, 70% by mass or less, 65% by mass, 60% by mass or less, 55% by mass or less, 50% by mass or less, 45% by mass or less, 35% by mass or less, or 30% by mass or less.

The adhesive film 12 may contain an imidazole compound. The imidazole compound includes a compound having an imidazole ring, and can function as, for example, a curing accelerator that accelerates a curing reaction between an epoxy resin and a curing agent (phenol resin or other resins) therefor. The type of the imidazole compound and the content thereof may be related to the maximum value of tan δ and the minimum melt viscosity of the adhesive film 12. An imidazole compound having a low softening point or melting point is likely to increase the maximum value of tan δ and the minimum melt viscosity. For example, at least one imidazole compound selected from the group consisting of 1-cyanoethyl-2-phenylimidazole, 2-phenylimidazole, and 1-benzyl-2-methylimidazole is likely to make obtaining an adhesive film having a maximum value of tan δ of 1.0 or less and/or a minimum melt viscosity of 2500 Pa·s or more easier.

As the content of the imidazole compound is large, the maximum value of tan δ and the minimum melt viscosity is likely to increase. For example, the content of the imidazole compound may be 0.06% by mass or more, 0.07% by mass or more, 0.08% by mass or more, 0.09% by mass or more, 0.10% by mass or more, or 0.11% by mass or more, and may be 1.0% by mass or less, 0.90% by mass or less, 0.80% by mass or less, 0.70% by mass or less, 0.60% by mass or less, 0.5% by mass or less, 0.40% by mass or less, 0.30% by mass or less, or 0.20% by mass or less based on the mass of the adhesive film 12.

In a case where the thermosetting resin contains an epoxy resin, from the same viewpoint as described above, the content of imidazole may be 0.30 parts by mass or more, 0.35 parts by mass or more, 0.40 parts by mass or more, 0.45 parts by mass or more, or 0.50 parts by mass or more, and may be 5.0 parts by mass or less, 4.5 parts by mass or less, 4.0 parts by mass or less, 3.5 parts by mass or less, 3.0 parts by mass or less, 2.5 parts by mass or less, 2.0 parts by mass or less, 1.5 parts by mass or less, 1.0 parts by mass or less, 0.95 parts by mass or less, 0.90 parts by mass or less, 0.85 parts by mass or less, 0.80 parts by mass or less, 0.75 parts by mass or less, 0.70 parts by mass or less, 0.65 parts by mass or less, or 0.60 parts by mass or less with respect to 100 parts by mass of the content of the epoxy resin.

Even though a curing accelerator other than the imidazole compound is used, an adhesive film having a maximum value of tan δ of 1.0 or less and/or a minimum melt viscosity of 2500 Pa·s or more can be obtained by appropriate adjustment of the reactivity, content, and other chemical properties thereof.

The adhesive film 12 may further contain an inorganic filler. In a case where the inorganic filler is introduced, the maximum value of tan δ and the minimum melt viscosity of the adhesive film 12 are likely to increase. The content of the inorganic filler may be 10% by mass or more, 15% by mass or more, 20% by mass or more, 25% by mass or more, 30% by mass or more, or 35% by mass or more, and may be 60% by mass or less, 55% by mass or less, 50% by mass or less, or 45% by mass or less based on the mass of the adhesive film 12.

The inorganic filler may include, for example, particles containing at least one inorganic material selected from aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whisker, boron nitride, and silica. From the viewpoint of adjusting a melt viscosity, the inorganic filler may contain silica.

The average particle diameter of the inorganic filler may be 0.01 μm or more, or 0.03 μm or more, and may be 1.5 μm or less, 1.0 μm or less, 0.8 μm or less, 0.08 μm or less, or 0.06 μm or less from the viewpoint of fluidity. Two or more kinds of inorganic fillers having different average particle diameters may be combined. The average particle diameter means a value determined by conversion from the BET specific surface area.

The adhesive film 12 may include an elastomer. In a case where the elastomer is introduced, the maximum value of tan δ and the minimum melt viscosity of the adhesive film 12 are likely to increase. The content of the elastomer may be 5% by mass or more, 10% by mass or more, or 15% by mass or more, and may be 50% by mass or less, 45% by mass or less, 40% by mass or less, 35% by mass or less, or 30% by mass or less, based on the mass of the adhesive film 12.

The elastomer may contain an acrylic resin. Here, the acrylic resin means a polymer containing a monomer unit derived from a (meth)acrylic acid ester. The content of a constituent unit derived from the (meth)acrylic acid ester in the acrylic resin may be, for example, 70% by mass or more, 80% by mass or more, or 90% by mass or more based on the total amount of the acrylic resin. The acrylic resin may contain a monomer unit derived from a (meth)acrylic acid ester having a crosslinkable functional group such as an epoxy group, an alcoholic or phenolic hydroxyl group, or a carboxyl group. The acrylic resin may be an acrylic rubber that is a copolymer containing a (meth)acrylic acid ester and acrylonitrile as monomer units.

The glass transition temperature (Tg) of the elastomer (for example, acrylic resin) may be −50° C. or higher, −30° C. or higher, 0° C. or higher, or 3° C. or higher, and may be 50° C. or lower, 45° C. or lower, 40° C. or lower, 35° C. or lower, 30° C. or lower, or 25° C. or lower. The glass transition temperature (Tg) means a value measured using a thermal differential scanning calorimetry (DSC) (for example, “Thermo Plus 2” manufactured by Rigaku Holdings Corporation). The Tg of the elastomer can be adjusted to fall within a desired range by adjustment of the type and content of a constituent unit (in the acrylic resin, a constituent unit is derived from a (meth)acrylic acid ester) that constitutes the elastomer.

The weight-average molecular weight (Mw) of the elastomer (for example, acrylic resin) may be 100000 or more, 200000 or more, or 300000 or more, and may be 3000000 or less, 2000000 or less, or 1000000 or less. In a case where the Mw of the elastomer is within such a range, the viscoelasticity of the adhesive film 12 is likely to be easily controlled appropriately. The Mw means a value that is measured by gel permeation chromatography (GPC) and converted using a calibration curve obtained by using standard polystylene.

Examples of commercially available products of the acrylic resin include SG-70L, SG-708-6, WS-023 EK30, SG-280 EK23, and SG-P3 (all of which are manufactured by Nagase ChemteX Corporation), and H-CT-865 (manufactured by Showa Denko Materials Electronics Co., Ltd.).

The adhesive film 12 may further contain a coupling agent. The coupling agent may be a silane coupling agent. Examples of the silane coupling agent include γ-ureidopropyltriethoxysilane, Y-mercaptopropyltrimethoxysilane, 3-phenylaminopropyltrimethoxysilane, 3-(2-aminoethyl)aminopropyltrimethoxysilane, and other silane coupling agents. These may be used singly or in combination of two or more kinds thereof.

The adhesive film 12 may further contain other components such as a pigment, an ion scavenger, and an antioxidant.

The base material 20 constituting the laminated film 50 may be a resin film, and examples thereof include a film containing polytetrafluoroethylene, polyethylene, polypropylene, polymethylpentene, polyethylene terephthalate, or polyimide. The thickness of the resin film serving as the base material 20 may be, for example, 60 to 200 μm or 70 to 170 μm.

The base material 20 may be a dicing film, and the laminated film 50 may be a dicing die-bonding film. The dicing die-bonding film may be in the form of a tape.

Examples of the dicing film include resin films such as a polytetrafluoroethylene film, a polyethylene terephthalate film, a polyethylene film, a polypropylene film, a polymethylpentene film, and a polyimide film. The dicing film may be a resin film surface-treated by primer coating, UV treatment, corona discharge treatment, polishing treatment, or etching treatment as necessary. The dicing film may have pressure-sensitive adhesiveness. The dicing film having pressure-sensitive adhesiveness may be, for example, a resin film to which pressure-sensitive adhesiveness is imparted, or a laminated body including the resin film and a pressure-sensitive adhesive layer provided on one surface thereof. The pressure-sensitive adhesive layer can be formed from a pressure-sensitive adhesive or an ultraviolet-curable pressure-sensitive adhesive. The pressure-sensitive adhesive includes a pressure-sensitive adhesive that exhibits constant pressure-sensitive adhesiveness when pressurized for a short time. The radiation-curable pressure-sensitive adhesive includes a pressure-sensitive adhesive having a property of reducing the pressure-sensitive adhesiveness by irradiation with radiation (for example, ultraviolet rays). The thickness of the pressure-sensitive adhesive layer can be appropriately set according to the shape and dimension of the semiconductor device, and may be, for example, 1 to 100 μm, 5 to 70 μm, or 10 to 40 μm. The thickness of the base material 20 serving as a dicing film may be 60 to 150 μm or 70 to 130 μm from the viewpoint of economic efficiency and film handleability.

The protective film 30 may be the same resin film as the base material 20. The thickness of the protective film 30 may be, for example, 15 to 200 μm or 70 to 170 μm.

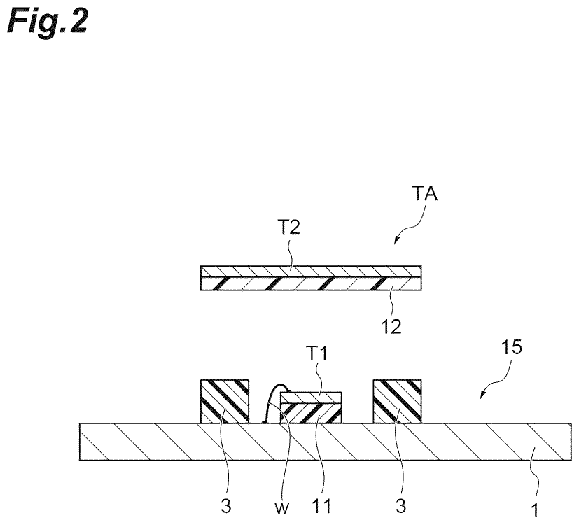

FIGS. 2, 3, 4, 5, and 6 are cross-sectional views illustrating an example of a method for manufacturing a semiconductor device using the adhesive film 12 described above.

As illustrated in FIG. 2, the example of the method for manufacturing a semiconductor device includes preparing a structure 15 having a substrate 1 and a first semiconductor chip T1 mounted on the substrate 1, and preparing an adhesive-backed chip TA that includes a second semiconductor chip T2 and an adhesive film 12 attached thereto. The structure 15 further includes a plurality of spacers 3 arranged around the first semiconductor chip on the substrate 1.

The first semiconductor chip T1 is bonded to the substrate 1 by a first adhesive film 11. The first semiconductor chip T1 is connected to a wire w at a surface opposite to the substrate 1. The first semiconductor chip T1 may be a controller chip. The substrate 1 may be an organic substrate or a metal substrate such as a lead frame. The thickness of the substrate 1 may be, for example, 90 to 300 μm. Each spacer 3 can be a spacer generally used in a semiconductor device having a dolmen structure. The height of each spacer 3 from the substrate 1 may be larger than the height of the first semiconductor chip T1 from the substrate 1.

The adhesive-backed chip TA including the second semiconductor chip T2 and the adhesive film 12 can be prepared using, for example, a dicing die-bonding film having the same configuration as the laminated film 50 exemplified in FIG. 1. In this case, for example, the laminated film 50 (dicing die-bonding film) is attached to one surface of a semiconductor wafer to be oriented such that the adhesive film 12 is brought into contact with the semiconductor wafer. The surface to which the adhesive film 12 is attached may be a circuit surface of the semiconductor wafer or a back surface on the opposite side thereto. The semiconductor wafer to which the laminated film 50 (dicing die-bonding film) is attached is divided by dicing to form individually divided second semiconductor chips T2. Examples of the dicing include blade dicing using a rotary blade, and a method for cutting the adhesive film 12 together with the semiconductor wafer by a laser. After the dicing, the pressure-sensitive adhesive force of the dicing film may be reduced by ultraviolet irradiation. The second semiconductor chip T2 is picked up together with a divided adhesive film 12.

The thickness of the second semiconductor chip may be, for example, 1 to 100 μm. The width of the second semiconductor chip T2 may be, for example, 20 mm or less. The width (or length of one side) of the second semiconductor chip T2 may be 3 to 15 mm or 5 to 10 mm.

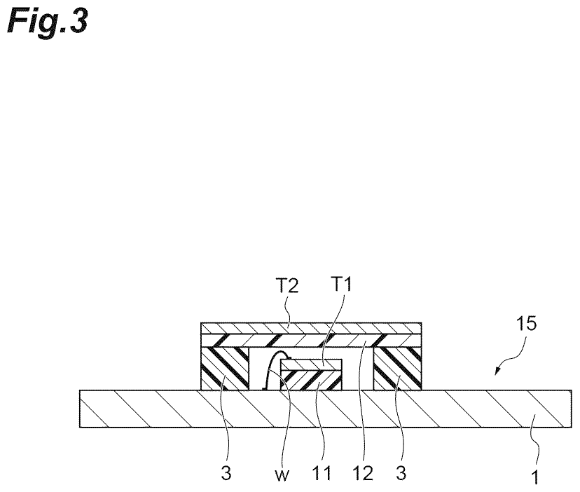

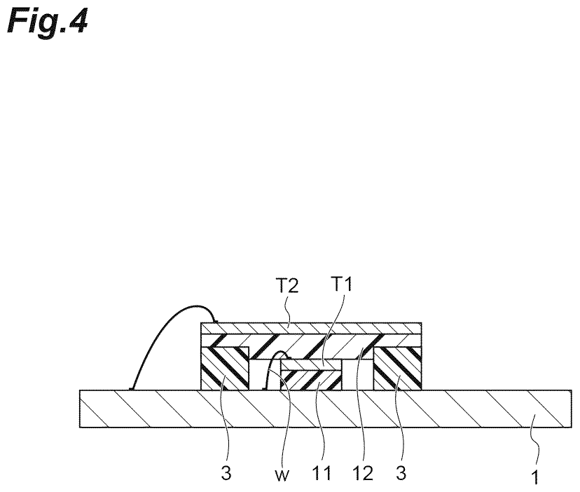

As illustrated in FIG. 3, the second semiconductor chip T2 and the adhesive film 12 are disposed on the structure 15 such that the adhesive film 12 is sandwiched between the structure 15 and the second semiconductor chip T2. For the example of FIG. 3, the adhesive film 12 is disposed on the spacer 3 of the structure 15, and the adhesive film 12 and the first semiconductor chip T1 are spaced from each other. The adhesive film 12 is thermally cured in this state to bond the second semiconductor chip T2 to the structure 15 (adherend) as illustrated in FIG. 4. The adhesive film 12 after thermal curing is in contact with the first semiconductor chip T1 and embeds a part of the wire w connected to the first semiconductor chip T1. The heating temperature for the thermal curing of the adhesive film 12 may be constant or gradually changed. The heating temperature may be up to 90° C. to 180° C. The adhesive film 12 is thermally cured under pressure, atmospheric pressure, or reduced pressure. The adhesive film 12 designed based on the maximum value of tan δ and/or the minimum melt viscosity can form a cured product that appropriately embeds the wire w through an appropriate flow in the thermal curing process, with the local deformation suppressed in the thickness direction.

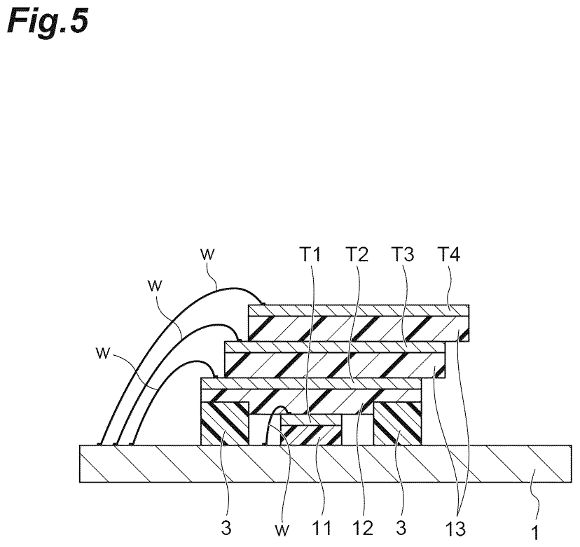

Subsequently, as illustrated in FIG. 5, the wire w connecting the second semiconductor chip T2 and the substrate 1 is provided. Furthermore, a third semiconductor chip T3 and a fourth semiconductor chip T4 may be sequentially stacked on the surface of the second semiconductor chip T2 opposite to the substrate 1 with adhesive films 13 interposed. A wire w connecting the third semiconductor chip T3 or the fourth semiconductor chip T4 and the substrate 1 is provided. For the example of FIG. 5, three semiconductor chips are stacked on the spacers 3, but four or more semiconductor chips may be stacked thereon.

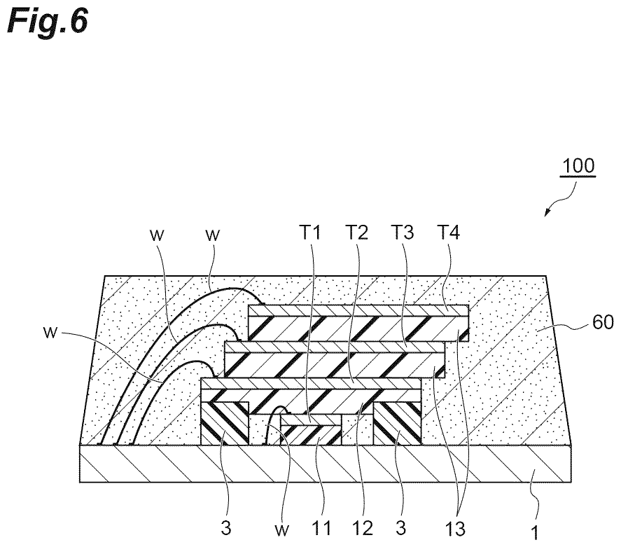

As illustrated in FIG. 6, by the formation of a sealing layer 60 that seals a structure including a plurality of semiconductor chips including the first semiconductor chip T1 and the second semiconductor chip T2, a semiconductor device 100 having a dolmen structure can be obtained. The vicinity of end portions of the first semiconductor chip is also filled with the sealing layer 60. In a case where the adhesive film 12 is locally deformed in the thickness direction, the sealing layer 60 may enter therein to cause defects such as cracks in the second semiconductor chip T2. Such defects can be avoided by suppression of the deformation of the adhesive film 12.

### EXAMPLES

The present invention is not limited to the following Examples.

### 1. Production of Adhesive Film

An adhesive varnish containing the following materials in the contents (unit: parts by mass) illustrated in Table 1 was prepared. The contents of SG-P3 (elastomer) and SC2050 HLG (silica filler) illustrated in Table 1 are the solid content (acrylic rubber or silica filler) excluding a solvent.

### (A) Epoxy Resin

N-500P-10 (trade name, manufactured by DIC Corporation, o-cresol novolac
epoxy resin, epoxy equivalent: 203 g/eq)
EXA-830CRP (trade name, manufactured by DIC Corporation, bisphenol F epoxy resin, epoxy equivalent: 158 to 168 g/eq)

### (B) Curing Agent (Phenol Resin)

MEH-7800M (trade name, manufactured by Meiwa Chemical Co., Ltd., phenol novolac phenol resin, hydroxyl equivalent: 175 g/eq, softening point: 61° C. to 90° C.)

### (C) Inorganic Filler

SC2050-HLG (trade name, manufactured by ADMATECHS COMPANY LIMITED, silica filler dispersion, average particle diameter: 0.50 μm)

### (D) Elastomer

SG-P3 (trade name, acrylic rubber, weight-average molecular weight: 800000, Tg: 12° C., cyclohexanone solution)

### (E) Coupling Agent

Z-6119 (trade name, manufactured by Dow Toray Co., Ltd., 3-ureidopropyltriethoxysilane)
A-189 (trade name, manufactured by Nippon Unicar Company Limited, γ-mercaptopropyltrimethoxysilane)

### (F) Curing Accelerator

2PZ-CN (trade name, manufactured by Shikoku Chemicals Corporation, 1-cyanoethyl-2-phenylimidazole)

Each of the prepared adhesive varnishes was filtered through a 500 mesh filter. Each of the filtered adhesive varnishes was vacuum-defoamed. The adhesive varnish after vacuum defoamation was applied onto a polyethylene terephthalate (PET) film (support film), which has been release-treated. The coating film was dried by two steps of heating at 90° C. for 5 minutes and subsequently heating at 130° C. for 5 minutes to form an adhesive film (thickness: 50 μm) in a B-stage state on the support film.

### 2. Evaluation

### (1) Viscoelasticity of Adhesive Film

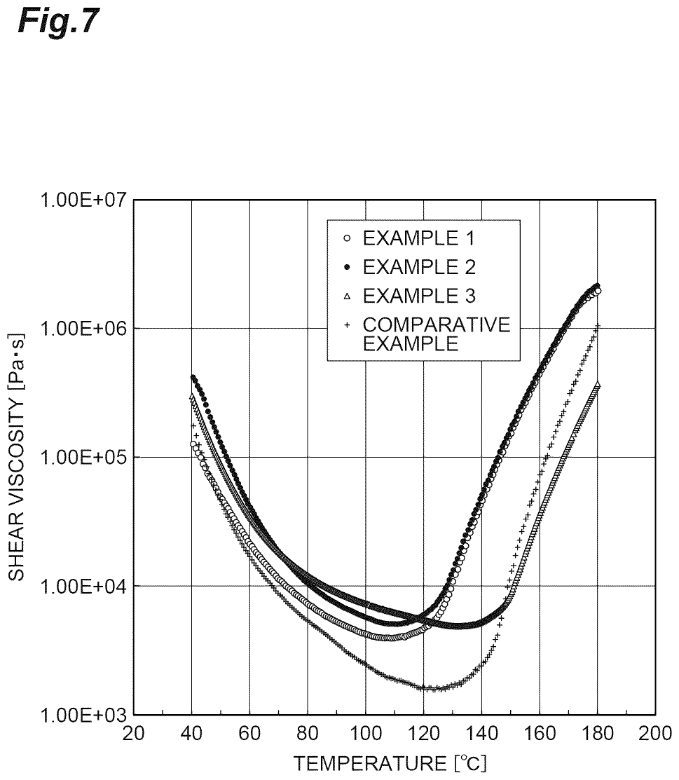

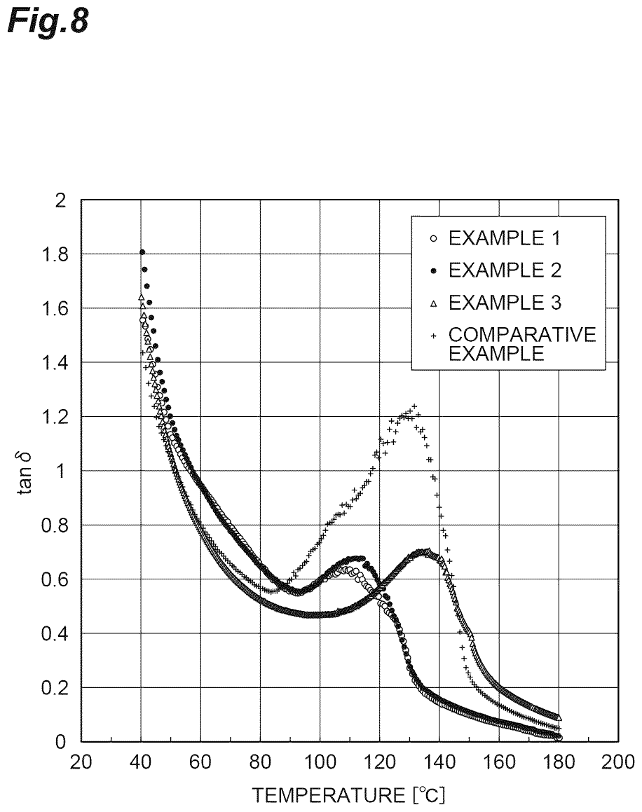

Eight adhesive films having a predetermined size cut out from the adhesive film were prepared. These were layered on a hot plate at 70° C. using a rubber roll to prepare a laminated body having a thickness of 400 μm. This laminated body was punched with a punch of φ9 mm to prepare a sample. The sample was mounted on a measurement jig of a rotary viscoelasticity measurement device (manufactured by TA Instruments Japan Inc., trade name: ARES-RDA). At this time, the gap of the measurement jig was adjusted such that the load applied to the sample was 10 to 15 g. Subsequently, the viscoelasticity of the sample was measured under the following conditions. FIG. 7 is a graph illustrating the relationship between the shear viscosity (complex viscosity) and the temperature of the adhesive films of Examples 1 to 3 and Comparative Example. FIG. 8 is a graph illustrating the relationship between the tan δ and the temperature of the adhesive films of Examples 1 to 3 and Comparative Example. From the measurement results, the minimum melt viscosity and the maximum value of tan δ in a range of 90° C. to 180° C. were read. The minimum melt viscosity is the minimum value of the shear viscosity (complex viscosity) in a range of 90° C. to 180° C.

### Measurement Conditions:

Disk plate: made of aluminum, circular (8 mmq)
Measurement frequency: 1 Hz
Temperature increasing rate: 5° C./min
Strain: 5%
Measurement temperature: 35° C. to 180° C.
Initial load: 100 g

### (2) Deformation of Adhesive Film

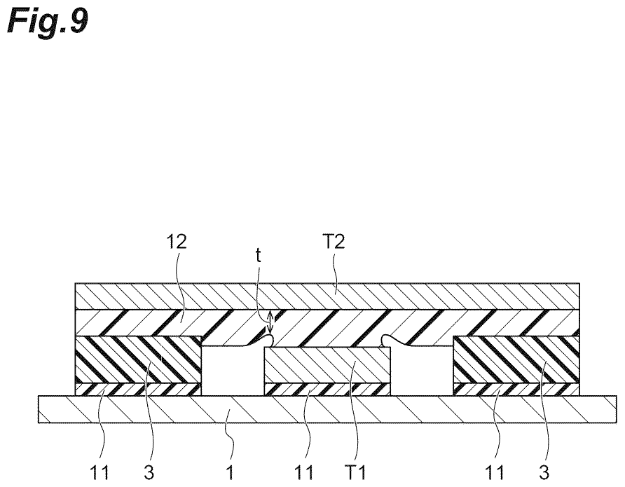

FIG. 9 is a schematic cross-sectional view illustrating an adherent for evaluation, which is used to evaluate deformation of the adhesive film associated with curing. A first semiconductor chip T1 (thickness: 60 μm) having a size of 3 mm×2 mm and four spacers 3 (thickness: 100 μm) surrounding the first semiconductor chip T1 were disposed on the substrate 1. The first semiconductor chip T1 and the spacers 3 were bonded to the substrate 1 by a first adhesive film 11 (thickness: 20 μm). The difference in height between the spacers 3 and the first semiconductor chip T1 on the substrate 1 was 40 μm. The distance between the first semiconductor chip T1 and each spacer 3 was 1.5 mm on the short side of the first semiconductor chip T1 and 1.0 mm on the long side of the first semiconductor chip T1.

An adhesive-backed chip including a second semiconductor chip T2 having a size of 12 mm×6 mm and a second adhesive film 12 attached thereto was prepared. As the second adhesive film 12, each adhesive film prepared in “1. Production of Adhesive Film” was used. The prepared adhesive-backed chip was pressure-bonded to the spacers 3 to cover the first semiconductor chip T1. The formed structure was heated in an oven at a maximum temperature of 140° C.; thereby, the second adhesive film 12 was cured. Thereafter, the location between the first semiconductor chip T1 and the cured adhesive film 12 of the structure was observed with an ultrasonic microscope (SAM) using an ultrasonic digital image diagnostic system (IS-350 or IS-450 manufactured by Insight k.k.). A case where a partial black shadow was not observed was evaluated as “OK”, and a case where a partial black shadow was observed was evaluated as “NG”. The partial black shadow is due to the deformation of the adhesive film 12, and it is considered that the adhesive film has good embeddability in the case where the partial black shadow is not observed. The conditions of the adhesive film SAM were as follows.
Reflection method
Frequency: 75 Hz
Focal length: 9 mm

In addition, the structure was cut in half, the adhesive film 12 in the cross-section was observed with an optical microscope, and a minimum value t of the thickness of the second adhesive film 12 was measured.

The evaluation results are illustrated in Table 1. It was confirmed that the adhesive films of Examples 1 to 5 were capable of suppressing local shrinkage in the thickness direction associated with curing. The adhesive film of Comparative Example was significantly deformed in the thickness direction in the vicinity of the end portions of the first semiconductor chip T1 by curing. As a result, a portion having a thickness of 0 μm, that is, a portion where the adhesive film 12 was substantially removed was observed. The adhesive films of Examples 1 to 5 were also excellent in embeddability.

TABLE 1

| | | Ex. 1 | Ex. 2 | Ex. 3 | Ex. 4 | Ex. 5 | Comp. Ex. |
|---|---|---|---|---|---|---|---|
| Epoxy resin | N-500P-10 | 10.4 | 9.4 | 8.7 | 9.2 | 9.7 | 10.4 |
| | EXA-830CRP | 13.0 | 11.2 | 10.9 | 11.5 | 12.1 | 13.0 |
| Curing agent | MEH-7800M | 19.2 | 16.1 | 16.0 | 16.9 | 17.8 | 19.2 |
| Inorganic filler | SC2050-HLG | 39.1 | 45.0 | 44.0 | 42.0 | 40.0 | 39.1 |
| Elastomer | SG-P3 | 18.0 | 18.0 | 20.0 | 20.0 | 20.0 | 18.0 |
| Silane coupling | Z-6119 | 0.18 | 0.18 | 0.18 | 0.09 | 0.09 | 0.18 |
| agent | A-189 | 0.09 | 0.09 | 0.09 | 0.18 | 0.18 | 0.09 |
| Imidazole compound | 2PZ-CN | 0.12 | 0.12 | 0.05 | 0.05 | 0.06 | 0.06 |
| Minimum melt viscosity [Pa · s] | | 3920 | 5030 | 4880 | 4550 | 4300 | 1560 |
| Maximum value of tanδ | | 0.63 | 0.66 | 0.70 | 0.60 | 0.59 | 1.23 |
| Deformation | Minimum value | 33 | 32 | 30 | 25 | 23 | 0 |
| of adhesive | of thickness [μm] | | | | | | |
| film | SAM | OK | OK | OK | OK | OK | NG |

### REFERENCE SIGNS LIST

1 Substrate
3 Spacer (thickness: 100 μm)
11, 12, 13 Adhesive film
15 Structure
20 Base material (dicing film)
30 Protective film
50 Laminated film (dicing die-bonding film)
60 Sealing layer
100 Semiconductor device
T1 First semiconductor chip
T2 Second semiconductor chip
W Wire

1. A thermosetting adhesive film for semiconductors, configured to bond a semiconductor chip to an adherend while embedding a wire connected to another semiconductor chip, wherein
the adhesive film has a minimum melt viscosity of 2500 Pa·s or more and 10000 Pa·s or less in a range of 90° C. to 180° C., and
the minimum melt viscosity is a value determined by measurement on a dynamic viscoelasticity of the adhesive film within a temperature range including a range of 90° C. to 180° C. under conditions of a temperature increasing rate of 5° C./min and a frequency of 1 Hz.

2. The adhesive film for semiconductors according to claim 1, wherein the adhesive film comprises a thermosetting resin comprising an epoxy resin, a curing agent, and an imidazole compound.

3. The adhesive film for semiconductors according to claim 2, wherein a content of the imidazole compound is 0.30 to 5.0 parts by mass with respect to 100 parts by mass of a content of the epoxy resin.

4. The adhesive film for semiconductors according to claim 1, wherein the adhesive film comprises an inorganic filler, and a content of the inorganic filler is 35% to 50% by mass based on a mass of the adhesive film.

5. The adhesive film for semiconductors according to claim 1, wherein the adhesive film comprises an elastomer, and a content of the elastomer is 15% to 30% by mass based on a mass of the adhesive film.

6. The adhesive film for semiconductors according to claim 1, wherein the adhesive film has a thickness of 25 to 80 μm.

7. A dicing die-bonding film comprising:
a dicing film; and
the adhesive film for semiconductors according to claim 1, the adhesive film being provided on the dicing film.

8. A method for manufacturing a semiconductor device, the method comprising:
disposing a second semiconductor chip and an adhesive film over a structure comprising a substrate and a first semiconductor chip mounted on the substrate such that the adhesive film is sandwiched between the structure and the second semiconductor chip; and
thermally curing the adhesive film to bond the second semiconductor chip to the structure, wherein
the adhesive film is the adhesive film for semiconductors according to claim 1,
the first semiconductor chip is connected to a wire, and
the adhesive film embeds a part of the wire or the wire as a whole.

9. The method according to claim 8, wherein
the structure further comprises a spacer disposed around the first semiconductor chip on the substrate, and
the second semiconductor chip and the adhesive film are disposed on the structure such that the adhesive film is sandwiched between the spacer and the second semiconductor chip.

10. The method according to claim 8, wherein the adhesive film is thermally cured such that the adhesive film is in contact with the first semiconductor chip.

11. The method according to claim 8, further comprising forming a sealing layer sealing the first semiconductor chip and the second semiconductor chip.
